(19) United States
(12) Patent Application Publication
(10) Pub. No.: US 2010/0173249 A1
(43) Pub. Date: Jul. 8, 2010

(54) Method for Manufacturing a Semiconductor Device

(75) Inventors: Jae Chang Jung, Seoul (KR); Sung Koo Lee, Seoul (KR)

Correspondence Address: MARSHALL, GERSTEIN & BORUN LLP, 233 SOUTH WACKER DRIVE, 6300 WILLIS TOWER, CHICAGO, IL, 60606-6357, US

(73) Assignee: HYNIX SEMICONDUCTOR INC., Icheon-si (KR)

(21) Appl. No.: 12/728,979

(22) Filed: Mar. 22, 2010

Related U.S. Application Data
(62) Division of application No. 11/427,578, filed on Jun. 29, 2006.

(30) Foreign Application Priority Data
Oct. 31, 2005 (KR) 10-2005-0103080

(51) Int. Cl. G03F 7/20

(52) U.S. Cl. 430/315; 430/319

(57) ABSTRACT

Disclosed herein is a composition for removing an immersion lithography solution. The composition includes an organic solvent and an acid compound. Also disclosed is a method for manufacturing a semiconductor device including an immersion lithography process. When a photoresist pattern is formed by the immersion lithography process, an exposure process is performed on a photoresist film formed over an underlying layer with an immersion lithography exposer. Then, the composition is dripped over the wafer to remove residual immersion lithography solution on the photoresist film, thereby improving a water mark defect phenomenon.

### CROSS-REFERENCE TO RELATED APPLICATIONS

This is a division of U.S. application Ser. No. 11/427,578 filed Jun. 29, 2006, which claims the priority benefit under 35 USC 119 of Korean patent application number 10-2005-0103080 filed Oct. 31, 2005, the entire respective disclosures of which are incorporated by reference.

### BACKGROUND OF THE INVENTION

1. Field of the Disclosure

The disclosure generally relates to a composition for removing an immersion lithography solution and a method for manufacturing a semiconductor device including an immersion lithography process using the same. More specifically, the disclosure relates to the composition for removing an immersion lithography solution effectively after performing immersion lithography process for manufacturing semiconductor devices of below 50 nm, and a method for manufacturing a semiconductor device including an immersion lithography process using the same.

2. Brief Description of Related Technology

As the fields of application of semiconductor devices have expanded, there has been a need to manufacture a memory device of high capacity with improved integrity. Semiconductor manufacturing processes necessarily include a lithography process.

In lithography process, although KrF (248 nm) or ArF (193 nm) as an exposure light source have been applied to exposure process, an attempts have been made to use short wavelength light sources such as F₂(157 nm) or EUV (13 nm) or to increase numerical apertures (NA).

However, when light sources of short wavelength are applied, a new exposer is required. As a result, use of light sources of short wavelength results in increased manufacturing costs. Also, the increase of numerical apertures degrades a focus depth width.

Recently, an immersion lithography process has been developed in order to solve these problems. While an existing exposure process utilizes air having a refractive index of 1.0 as a medium of exposure beams between a wafer having a photoresist film and an exposure lens of an exposer, the immersion lithography process utilizes a solution such as H₂O or an organic solvent having a refractive index of more than 1.0 as a medium of exposure beams.

As a result, when the lithography process using KrF or ArF as an exposure light source is performed, the same effect is obtained as when a light source of a short wavelength is used or a lens having high numerical apertures is used, without degradation depth of focus.

Meanwhile, the immersion lithography process includes performing an exposure process with solution as the medium, rotating a wafer to remove an immersion lithography solution, baking and developing the resulting structure to form a pattern. Here, because a solution having a high specific heat has been used as the immersion lithography solution, the solution remains on the photoresist film after the lithography solution is removed to cause a water mark defect with a circular bridge type on the wafer as shown in FIG. 1.

### SUMMARY OF THE DISCLOSURE

Disclosed herein is a composition for removing an immersion lithography solution. The composition includes an organic solvent having a boiling point of below 150° C., and an acid compound present in an amount ranging from 0.005 to 10 parts by weight based on 100 parts by weight of the organic solvent.

Also disclosed herein is a method for manufacturing a semiconductor device including an immersion lithography process. The method includes forming a photoresist film over an underlying layer on a wafer, and selectively exposing the photoresist film with an immersion lithography exposer using an immersion lithography solution. The method also includes; removing residual immersion lithography solution remaining on the photoresist film using the aforementioned composition, and developing the resulting structure to obtain a photoresist pattern.

The disclosed method and composition are useful to reduce a water mark defect on the wafer.

### BRIEF DESCRIPTION OF THE DRAWING FIGURES

For a more complete understanding of the invention, reference should be made to the following detailed description and accompanying drawings wherein:

FIG. 1 is a SEM photograph illustrating a water mark defect generated on a pattern after a conventional immersion lithography solution is removed;

FIG. 2 is a SEM photograph illustrating a bridge defect generated on a pattern after an immersion lithography solution is removed by dripping n-pentanol; and

FIG. 3 is a SEM photograph illustrating a pattern having no water mark defects when an immersion lithography solution is removed by dripping a composition in accordance with the invention.

While the disclosed composition and method are susceptible of embodiments in various forms, there are illustrated in the drawing (and will hereafter be described) specific embodiments of the invention, with the understanding that the disclosure is intended to be illustrative, and is not intended to limit the invention to the specific embodiments described and illustrated herein.

### DETAILED DESCRIPTION OF THE INVENTION

There is provided a composition for removing an immersion lithography solution. The disclosed composition generally comprises an organic solvent and an acid compound.

Preferably, the disclosed composition has the following characteristics:

a) it is easy to treat the composition;

b) the composition has a low solubility to a general photoresist film;

c) the boiling point of the composition is preferably below 150° C. to reduce a specific heat of the immersion lithography solution; and

d) the volatility of the composition is high so that the composition can be easily evaporated when a wafer is rotated.

The organic solvent includes linear or branched C₅-C₇ alkane or linear or branched C₃-C₇ alcohol having a boiling point of below 150° C. Preferably, the organic solvent is selected from the group consisting of n-pentane, n-hexane, iso-pentane, n-pentanol, iso-pentanol, and iso-hexanol.

The acid compound present in the composition prevents an acid generated from a photoacid generator during an exposure process from dissolving in the composition. Preferably, the acid compound has a pH of below 3, and the acid compound includes p-toluenesulfonic acid monohydrate or methanesulfonic acid.

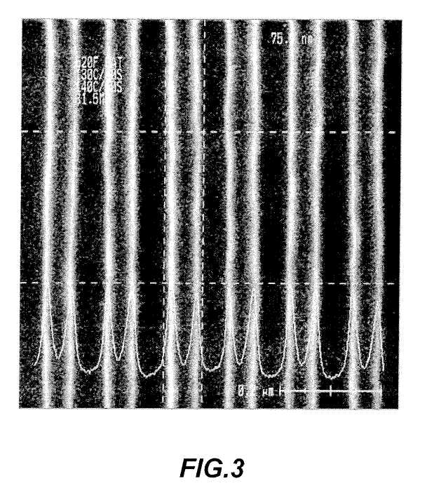

The acid compound is present in an amount ranging from 0.005 to 10 parts by weight, preferably from 0.05 to 1 parts by weight, based on 100 parts by weight of the organic solvent. When the acid compound is present in the amount of less than 0.005 parts by weight, an acid generated from a photoresist film during the exposure process is dissolved together when the lithography solution is removed so that a photoresist pattern with a T-top shape or a pattern bridge phenomenon (a) is generated (see FIG. 2). On the other hand, when the acid compound is present in the amount of more than 10 parts by weight, the unexposed portion of the photoresist film is dissolved in a dissolving solution during a subsequent developing process.

Also, there is provided a method for manufacturing a semiconductor device including an immersion lithography process using the disclosed composition. The method includes (a) forming a photoresist film over an underlying layer on a wafer; (b) selectively exposing the photoresist film with an immersion lithography exposer using an immersion lithography solution; (c) removing residual immersion lithography solution remaining on the photoresist film using the disclosed composition; and, (d) developing the resulting structure to obtain a photoresist pattern.

Although any photoresist materials for forming the photoresist film can be used, a photoresist material may be a chemically amplification-type photoresist composition including a photoacid generator. Preferably, the photoresist material is a photoresist composition including a photoresist polymer comprising a novolak compound as a main chain (disclosed in Korean Patent No. 2005-521421) or a photoresist co-polymer of cycloolefin monomer and maleic anhydride as a main chain (disclosed in Korean Patent No. 2002-362935, 2005-520167 and 2005-403326).

Before forming a photoresist film in the step (a), the method may further include forming a bottom anti-reflectivity coating film over the underlying layer with an inorganic film selected from the group consisting of titanium, titanium dioxide, titanium nitride, and silicon, or with an organic film selected from the group consisting of phenylamine resin, melamine derivative resin, alkali soluble resin, acrylate rein, and epoxy resin.

After forming the photoresist film in the step (a), the method may further include forming a top anti-reflectivity coating film over the photoresist film with an acrylate resin having a high solubility to the organic solvent such as n-pentanol or iso-pentanol, for example, an acrylate resin whose linear or branched chain is substituted with fluorine.

The light source exposer used in the step (b) preferably is selected from the group consisting of KrF (248 nm), ArF (193 nm), VUV (157 nm), EUV (13 nm), E-beam, X-ray, and ion-beam. Preferably, the disclosed composition is suitable for the exposure process with KrF or ArF. The exposing step is preferably performed with an exposure energy ranging from about 0.1 mJ/cm²to about 100 mJ/cm².

The removing step (c) preferably includes (i) while rotating a wafer at 200 to 300 rpm, slow dripping the disclosed composition on the rotating wafer for 5 to 15 seconds; and, (ii) rapidly rotating the wafer again at 3000 to 15000 rpm for 1 to 3 minutes to remove the residual immersion lithography solution remaining on the photoresist film.

The disclosed composition in the step (i) is dripped in an amount of at least 50 ml per wafer. Preferably, the disclosed composition is used drippedin the step (i) in an amount ranging from 50 to 400 ml per wafer. While the water mark defect is not completely removed when the composition is present in the amount of less than 50 ml, there is no difference in the effect when the composition is present in the amount of more than 400 ml.

Also, the water mark defect is not completely removed when the rotating speed of the wafer is less than 3000 rpm in the step (ii) while a stress is applied to a rotating motor when the speed is more than 15000 rpm.

The disclosed method may be performed on all wafers including a line pattern or a hole pattern.

The disclosed method will be described in detail by referring to examples below, which are not intended to limit the present invention.

Meanwhile, an exposer for immersion lithography (1400i produced by ASML Co.) with H₂O as a medium was used in the following Comparative Examples and Examples. The water mark defect was examined by a defect measuring device (produced by KLA Co.), and the examined results were the total number of the water mark defects generated in the overall 8 Inch wafer.

### I. Preparation of a Composition for Removing an Immersion Lithography Solution

### Examples 1 to 5 and Comparative Examples 1 to 3

### Composition for Removing an Immersion Lithography Solution

An organic solvent was mixed with an acid compound at room temperature as shown in Table 1, and then the resulting mixture was filtered with a 0.02 μm filter to obtain a disclosed composition for removing an immersion lithography solution of Examples 1 to 5, and a composition for removing an immersion lithography solution of Comparative Examples 1 to 3.

TABLE 1

| | | Organic Solvent | Acid Compound |
|---|---|---|---|
| Example | 1 | A (1000 g) | C (0.05 g) |
| | 2 | A (1000 g) | C (0.2 g) |
| | 3 | A (1000 g) | C (90 g) |
| | 4 | B (1000 g) | D (0.2 g) |
| | 5 | B (1000 g) | D (10 g) |
| Comparative | 1 | A (1000 g) | — |
| Example | 2 | A (1000 g) | C (0.01 g) |
| | 3 | A (1000 g) | C (110 g) |

A: n-pentanol (produced by Aldrich Co.)
B: iso-hexanol (produced by Aldrich Co.)
C: p-toluensulfonic acid monohydrate (produced by Aldrich Co.)
D: methanesulfonic acid (produced by Aldrich Co.)

### II. Formation of a Pattern of a Semiconductor Device by an Immersion Lithography Process

### Example 6

### Immersion Lithography Process Using a Disclosed Composition (1)

A spin-coating process was performed on a wafer including an oxide film as an underlying layer to form a bottom anti-reflectivity coating film (A25 BARC produced by Dongjin Semichem Co.) and a 0.17 μm ArF photoresist (X121 produced by Shinetsu Co.) sequentially. The wafer was baked at 130° C. for 90 seconds, and a top anti-reflectivity coating film for immersion (ARC 20 produced by Nissan Chemistry Co.) was coated over the photoresist. Then, the wafer was baked at 90° C. for 60 seconds. After the resulting structure was exposed by an immersion lithography exposer with ArF and water (H₂O) as a medium, the composition for removing an immersion lithography solution of Example 1 (200 ml) was dripped over the wafer for about 10 seconds while the wafer was rotating at 200 rpm. After dripping, the wafer was rapidly rotated at 5000 rpm for 1 minute to remove the residual immersion lithography solution (H₂O) on the photoresist film. Thereafter, the resulting structure was baked at 130° C. for 90 seconds. Then, it was developed in 2.38 wt % tetramethyl ammonium hydroxide (TMAH) aqueous solution for 30 seconds, thereby obtaining a photoresist pattern without any water mark defect and bridge (see Table 2 and FIG. 3).

### Example 7

### Immersion Lithography Process Using a Disclosed Composition (2)

The Example 6 was repeated using the composition of Example 2 instead of that of Example 1, thereby obtaining a pattern without any water mark defect and bridge (see Table 2).

### Example 8

### Immersion Lithography Process Using a Disclosed Composition (3)

The Example 6 was repeated using the composition of Example 3 instead of that of Example 1, thereby obtaining a pattern without any water mark defect and bridge (see Table 2).

### Example 9

### Immersion Lithography Process Using a Disclosed Composition (4)

The Example 6 was repeated using the composition of Example 4 instead of that of Example 1, thereby obtaining a pattern without any water mark defect and bridge (see Table 2).

### Example 10

### Immersion Lithography Process Using a Disclosed Composition (5)

The Example 6 was repeated using the composition of Example 5 instead of that of Example 1, thereby obtaining a pattern without any water mark defect and bridge (see Table 2).

### Comparative Example 4

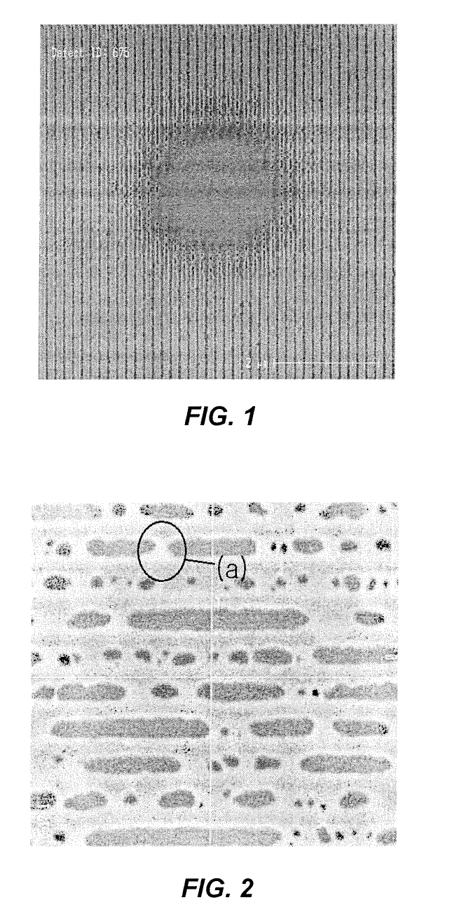

A spin-coating process was performed on a wafer including an oxide film as an underlying layer to form a bottom anti-reflectivity coating film (A25 BARC produced by Dongjin Semichem Co.) and a 0.17 μm ArF photoresist (X121 produced by Shinetsu Co.) sequentially. The wafer was baked at 130° C. for 90 seconds, and exposed by an immersion lithography exposer with ArF and water (H₂O) as a medium. After the exposure process, the wafer was rotated at 5000 rpm for about 2 minutes to remove water as the immersion lithography solution (H₂O) on the photoresist film. Next, the resulting structure was baked at 130° C. for 90 seconds. Then, it was developed in 2.38 wt % TMAH aqueous solution for 30 seconds, thereby obtaining a photoresist pattern having about 2000 water mark defects as shown in FIG. 1 (see Table 2).

### Comparative Example 5

A spin-coating process was performed on a wafer including an oxide film as an underlying layer to form a bottom anti-reflectivity coating film (A25 BARC produced by Dongjin Semichem Co.) and a 0.17 μm ArF photoresist (X121 produced by Shinetsu Co.) sequentially. The wafer was baked at 130° C. for 90 seconds, and a top anti-reflectivity coating film (ARC 20 produced by Nissan Chemistry Co.) was coated over the photoresist. Then, the resulting structure was baked at 90° C. for 60 seconds, and exposed by an immersion lithography exposer with ArF and water (H₂O). After the exposure process, the wafer was rotated at 5000 rpm for about 2 minutes to remove the immersion lithography solution (H₂O) on the photoresist film. Next, the resulting structure was baked at 130° C. for 90 seconds. Then, it was developed in 2.38 wt % TMAH aqueous solution for 30 seconds, thereby obtaining a photoresist pattern having about 140 water mark defects (see Table 2).

### Comparative Example 6

A spin-coating process was performed on a wafer including an oxide film as an underlying layer to form a bottom anti-reflectivity coating film (A25 BARC produced by Dongjin Semichem Co.) and a 0.17 μm ArF photoresist (X121 produced by Shinetsu Co.) sequentially. The wafer was baked at 130° C. for 90 seconds, and a top anti-reflectivity coating film (ARC 20 produced by Nissan Chemistry Co.) was coated over the photoresist. Then, the resulting structure was baked at 90° C. for 60 seconds, and exposed by an immersion lithography exposer with ArF and water (H₂O) as a medium. After the exposure process, the composition of Comparative Example 1 (200 ml) was dripped over the wafer while the wafer was rotated at 200 rpm for about 10 seconds. After dripping, the wafer was rapidly rotated at 5000 rpm for 1 minute to remove the immersion lithography solution (H₂O) on the photoresist film. Thereafter, the resulting structure was baked at 130° C. for 90 seconds. After baking, it was developed in 2.38 wt % TMAH aqueous solution for 30 seconds, thereby obtaining a photoresist pattern having a bridge (a) as shown in FIG. 2 (see Table 2).

### Comparative Example 7

The procedure of Comparative Example 6 was repeated using the composition of Comparative Example 2 instead of that of Comparative Example 1, thereby obtaining a pattern having a bridge (see Table 2).

### Comparative Example 8

The procedure of Comparative Example 6 was repeated using the composition of Comparative Example 3 instead of that of Comparative Example 1. As a result, most of photoresist layers were dissolved so that patterns are not formed (see Table 2).

TABLE 2

| | Example | | | | | Comparative Example | | | | |
|---|---|---|---|---|---|---|---|---|---|---|
| | 6 | 7 | 8 | 9 | 10 | 4 | 5 | 6 | 7 | 8 |
| formed | ▪ | ▪ | ▪ | ▪ | ▪ | ▴ | ▴ | ∘ | ∘ | x |
| pattern | | | | | | | | | | |

▪: pattern without any water mark defect and bridge
▴: pattern having a plurality of water mark defects
∘: pattern having a bridge
x: pattern was not formed

As described above, a disclosed composition for removing an immersion lithography solution is used in a method for forming a pattern of a semiconductor device including an immersion lithography process, thereby improving a water mark defect phenomenon effectively.

What is claimed is:

1. A method for manufacturing a semiconductor device including an immersion lithography process, the method comprising:
(a) forming a photoresist film over an underlying layer on a wafer;
(b) selectively exposing the photoresist film with an immersion lithography exposer using an immersion lithography solution;
(c) removing residual immersion lithography solution remaining on the photoresist film using a composition comprising an organic solvent having a boiling point of below 150° C., and an acid compound present in an amount ranging from 0.005 to 10 parts by weight, based on 100 parts by weight of the organic solvent; and,
(d) developing the resulting structure to obtain a photoresist pattern.

2. The method according to claim 1, wherein the photoresist film is formed with a chemically amplification-type photoresist composition.

3. The method according to claim 2, wherein the chemically amplification-type photoresist composition includes a photoresist polymer comprising a novolak compound or a photoresist copolymer of cycloolefin monomer and maleic anhydride as a main chain.

4. The method according to claim 1, further comprises forming a bottom anti-reflectivity coating film before forming the photoresist film.

5. The method according to claim 4, wherein the bottom anti-reflectivity coating film is formed with an inorganic film selected from the group consisting of titanium, titanium dioxide, titanium nitride, and silicon.

6. The method according to claim 4, wherein the bottom anti-reflectivity coating film is formed with an organic film selected from the group consisting of phenylamine resin, melamine derivative resin, alkali soluble resin, acrylate rein, and epoxy resin.

7. The method according to claim 1, further comprises forming a top anti-reflectivity coating film over the photoresist film after forming the photoresist film.

8. The method according to claim 7, wherein the top anti-reflectivity coating film is formed with acrylate resin.

9. The method according to claim 1, wherein the removing step (c) comprises:
(i) while rotating a wafer at 200 to 300 rpm, slow dripping the composition on the rotating wafer for 5 to 15 seconds;
(ii) rapidly rotating the wafer again at 3000 to 15000 rpm for 1 to 3 minutes to remove residual immersion lithography solution remaining on the photoresist film.

10. The method according to claim 9, wherein the composition is present dripped in an amount of at least 50 ml per wafer.

11. The method according to claim 10 wherein the composition is present dripped in an amount ranging from 50 to 400 ml per wafer.
